(19) United States
(12) Patent Application Publication
(10) Pub. No.: US 2014/0144681 A1
(43) Pub. Date: May 29, 2014

(54) ADHESIVE METAL NITRIDE ON GLASS AND RELATED METHODS

(71) Applicant: QUALCOMM MEMS TECHNOLOGIES, INC., San Diego, CA (US)

(72) Inventors: Victor Louis Arockiaraj Pushparaj, Sunnyvale, CA (US); Ravindra V. Shenoy, Dublin, CA (US); Jon Bradley Lasiter, Stockton, CA (US); Kwan-Yu Lai, San Jose, CA (US); Donald William Kidwell, Los Gatos, CA (US); Ana Rangelova Londergan, Santa Clara, CA (US)

(73) Assignee: QUALCOMM MEMS TECHNOLOGIES, INC., San Diego, CA (US)

(21) Appl. No.: 13/686,620

(22) Filed: Nov. 27, 2012

(51) Int. Cl. H05K 1/03; B32B 7/12; H05K 1/16; B32B 3/30; C23C 28/00; H05K 1/09; C23C 16/02; B32B 3/26

(52) U.S. Cl. CPC H05K 1/0306; C23C 16/0254; C23C 16/0263; B32B 7/12; B32B 3/266; B32B 3/30; C23C 28/322; C23C 28/34; H05K 1/09; H05K 1/162
USPC 174/257; 427/58; 427/555; 427/126.1; 427/123; 428/164; 428/137; 205/162; 174/258

(57) ABSTRACT

This disclosure provides systems, methods and apparatus for an adhesive metal nitride layer on glass. In one aspect, a glass substrate having a surface is provided. A via with a depth to width aspect ratio of 5 to 1 or greater extends at least partially through the glass substrate. An adhesive metal nitride layer is disposed on the surface of the glass substrate and on one or more interior surfaces of the via. The adhesive metal nitride layer includes at least one of titanium nitride and tantalum nitride.

### TECHNICAL FIELD

This disclosure relates to components on glass surfaces, such as adhesion layers on glass surfaces and through-glass vias in electromechanical systems and devices.

### DESCRIPTION OF THE RELATED TECHNOLOGY

Devices, including EMS devices, can be fabricated on glass substrates and other glass surfaces. In addition, many device packages can include glass substrates. Formation of thin films, nanostructures, and/or microstructures on surfaces of glass substrates can increase the functionality of glass substrates.

### SUMMARY

The systems, methods and devices of this disclosure each have several innovative aspects, no single one of which is solely responsible for the desirable attributes disclosed herein.

One innovative aspect of the subject matter described in this disclosure can be implemented in an apparatus including a glass substrate having a surface, a via extending at least partially through the glass substrate from the surface, and an adhesive metal nitride layer disposed on the surface of the glass substrate and on one or more interior surfaces of the via. The via has a depth to width aspect ratio of 5 to 1 or greater, and the adhesive metal nitride layer includes at least one of titanium nitride (TiN) and tantalum nitride (TaN).

In some implementations, the via extends entirely through the glass substrate. The adhesive metal nitride layer may be conformally deposited on the surface of the glass substrate and on the one or more interior surfaces of the via and continuously coats the one or more surfaces of the via. The apparatus may further include a copper (Cu) layer on the adhesive metal nitride layer. In some implementations, the Cu layer substantially fills the via and forms part of an electrically conductive interconnect of an interposer. In some implementations, the Cu layer includes at least one of electroless Cu and electroplated Cu. In some implementations, the apparatus includes a dielectric layer over the adhesive metal nitride layer, and an outer metal nitride layer over the dielectric layer, where the outer metal nitride layer includes at least one of TiN and TaN, and where the adhesive metal nitride layer, the dielectric layer, and the outer metal nitride layer form part of a metal-insulator-metal (MIM) capacitor in the via. The apparatus can further include a first Cu layer between the dielectric layer and the adhesive metal nitride layer, and a second Cu layer between the dielectric layer and the outer metal nitride layer. In some implementations, the glass substrate has a thickness between about 50 μm and about 1100 μm. In some implementations, the adhesive metal nitride layer is a diffusion barrier.

Another innovative aspect of the subject matter described in this disclosure can be implemented in an apparatus including a glass substrate having a surface, a via extending at least partially from the surface through the glass substrate, means for adhering an electrically conductive material to glass disposed on the surface of the glass substrate and on the interior surface of the via, and means for conducting electricity formed on the adhering means to at least partially fill the via. The via has an interior surface and an aspect ratio of depth to width of 5 to 1 or greater. The conducting means includes the electrically conductive material.

In some implementations, the adhering means includes at least one of titanium nitride (TiN) and tantalum nitride (TaN). In some implementations, the adhering means is conformally deposited on the surface of the glass substrate and on the interior surface of the via. In some implementations, the apparatus can further include a first buffering means for providing a buffer for the conducting means where the first buffering means includes at least one of TiN and TaN, means for insulating electricity formed over the first buffering means, a second buffering means for providing a buffer for the insulating means where the second buffering means includes at least one of TiN and TaN, and a second means of conducting electricity formed over the second buffering means where the second conducting means includes Cu.

Another innovative aspect of the subject matter described in this disclosure can be implemented in method including providing a via through a glass substrate, depositing by atomic layer deposition (ALD) an adhesive layer on a surface of the glass substrate and on the interior surface of the via, and forming an electrically conductive layer on the adhesive layer to at least partially fill the via. The via has an interior surface and has an aspect ratio of depth to width of 5 to 1 or greater.

In some implementations, providing the via includes forming the via by laser drilling. In some implementations, the adhesive layer includes at least one of titanium nitride (TiN) and tantalum nitride (TaN). In some implementations, the conductive layer includes at least one of electroless Cu and electroplated Cu. In some implementations, the method further includes depositing a first buffer metal nitride layer over the conductive layer, and depositing a dielectric layer over the first metal nitride layer, where the dielectric layer has a thickness between about 5 nm and about 100 nm.

Details of one or more implementations of the subject matter described in this disclosure are set forth in the accompanying drawings and the description below. Although the examples provided in this disclosure are primarily described in terms of EMS and MEMS-based displays the concepts provided herein may apply to other types of displays such as liquid crystal displays, organic light-emitting diode (“OLED”) displays, and field emission displays. Other features, aspects, and advantages will become apparent from the description, the drawings and the claims. Note that the relative dimensions of the following figures may not be drawn to scale.

### BRIEF DESCRIPTION OF THE DRAWINGS

FIG. 1 shows an image of a cross-section of a glass substrate with a through-glass via.

FIGS. 2A-2C are examples of cross-sectional schematic illustrations of through-glass vias.

FIG. 3 is an example of a cross-sectional schematic illustration of an adhesive metal nitride layer disposed on the surface of a glass substrate and on the interior surfaces of a through-glass via.

FIG. 4A is an example of a cross-sectional schematic illustration of a copper fill over an adhesive metal nitride layer in a through-glass via.

FIG. 4B is an example of a cross-sectional schematic illustration of a copper thin film over an adhesive metal nitride layer in a through-glass via.

FIGS. 5A-5C are examples of cross-sectional schematic illustrations of an adhesive metal nitride layer as part of a capacitor in a through-glass via according to varying implementations.

FIGS. 6A-6C are examples of cross-sectional schematic illustrations of an adhesive metal nitride layer as part of a capacitor in a blind via according to varying implementations.

FIG. 7 is an example of a flow diagram illustrating a method of forming an electrically conductive layer on an adhesive layer to at least partially fill a via through a glass substrate.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can use through-glass vias for various applications, including routing signals from one side or surface of a glass substrate to an opposite side or surface of the glass substrate. It is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Some implementations described herein relate to a via extending at least partially through a glass substrate having a surface, with the via having a depth to width aspect ratio of 5 to 1 or greater. An adhesive metal nitride layer can be disposed on the surface of the glass substrate and on one or more interior surfaces of the via. The adhesive metal nitride layer can include at least one of titanium nitride (TiN) and tantalum nitride (TaN). Various materials and/or microstructures can be formed over the adhesive metal nitride layer. In some implementations, a copper (Cu) layer is disposed on the adhesive metal nitride layer. The Cu can substantially fill the via or form a thin film over the adhesive metal nitride layer. In some implementations, a dielectric layer is disposed over the adhesive metal nitride layer and another metal nitride layer is disposed over the dielectric layer to form part of a metal-insulator-metal (MIM) capacitor in the via.

Particular implementations of the subject matter described in this disclosure can be implemented to realize one or more of the following potential advantages. An adhesive metal nitride layer can serve to improve adhesion of subsequently deposited materials, such as Cu, over a glass surface. The adhesive metal nitride layer can be very thin and substantially uniform. The adhesive metal nitride layer also can serve as a diffusion barrier layer so that impurities, such as Cu ions, do not migrate into a glass substrate. Such a barrier layer can help reduce insertion loss. The adhesive metal nitride layer also can conformally and continuously deposit on the interior surfaces of a via extending at least partially through the glass substrate. The adhesive metal nitride layer can continuously coat the interior surface of the via so that the interior surface is fully coated. Thus, subsequently deposited materials, thin films, microstructures, and/or nanostructures can be formed in high aspect ratio vias. For example, a high density MIM capacitor can be formed on the sidewalls of the vias. In addition, the adhesive metal nitride layer can serve as a seed layer for subsequently deposited materials, such as Cu.

In some implementations, a glass substrate with a via extending at least partially through the glass substrate can be part of a package for an EMS or MEMS device or apparatus.

MEMS, EMS, optoelectronic, and integrated circuit (IC) technologies have seen an increasing interest in improving performance based on using various types of substrates. In a 3-D device structure, electronic components such as semiconductor chips, EMS devices, radio-frequency (RF) devices, and the like can be provided in a stacked structure. In such structures, the choice of the substrate can provide significant advantages, such as advantages in cost, electrical properties, thermal properties, mechanical properties, chemical properties, and processability. Insulating substrates such as glass substrates can provide a low-cost alternative to other substrates, including conventional semiconducting substrates such as silicon (Si) and silicon-on-insulator (SOI). In some implementations, glass substrates can serve as a low-cost alternative because, for example, passive devices may be spread over a larger area of a glass substrate compared to other substrates, or span the top and bottom sides of a glass substrate, which can make fabricating passive devices on glass relatively inexpensive. Through-glass vias can enable increased use of glass as a substrate for EMS and electronic components, and can improve the packaging and interconnection for devices presently being fabricated or packaged onto glass substrates.

In addition, forming passives on glass can lead to improved performance in various applications, with reduced losses, higher Q, lower parasitics, and higher reliability as a result in part of the insulating properties of glass. Furthermore, forming interposers in glass can reduce loss, provide high-wiring density interconnection, reduce coefficient of thermal expansion (CTE) mismatch to connected dies, reduce undesired coupling between electrical terminals, reduce electrical line lengths, and otherwise improve electrical performance.

Implementations described herein relate to device packaging and glass substrates. Glass substrates can include any suitable type of glass known in the art, including but not limited to photoglass, borosilicate glass, soda lime glass, quartz, Pyrex, or other glass material. Photoglass or photodefinable glass is a class of glass with light-activated precursors added during glass formation. Photoglass also permits higher densities, multiple layers, and custom design patterns. Photoglass materials can include glass materials containing silicon oxide/lithium oxide-based glasses doped with one or more noble metals such as silver and cerium.

The thickness of the glass substrate can be between about 10 microns and about 1100 microns. The glass substrate thickness can vary according to implementation. For example, in certain implementations, where the glass substrate is a MEMS device substrate that is to be further packaged, the thickness can be between about 10 microns and about 300 microns, such as between about 50 microns and 300 microns. In some implementations, where the glass substrate includes surface mount device (SMD) pads and is configured to mount onto a printed circuit board (PCB), the thickness may be at least about 300 microns, such as between about 300 microns and about 500 microns. In some implementations, the glass substrate can include one or more panels and can have a thickness of at least 700 microns, such as between about 700 microns and about 1100 microns.

Glass substrates in device packaging can provide several advantages: high resistivity, low loss tangent, smooth surface finish, large area availability, high strength, resistance to process chemicals, and low cost per input/output (I/O) for 25 micron pitch. As electronic devices go to smaller pitches, glass substrates can reduce leakage and losses between features with tighter geometries. Moreover, glass substrates are relatively inert, have good planarity, and are thermally stable at subsequent processing temperatures.

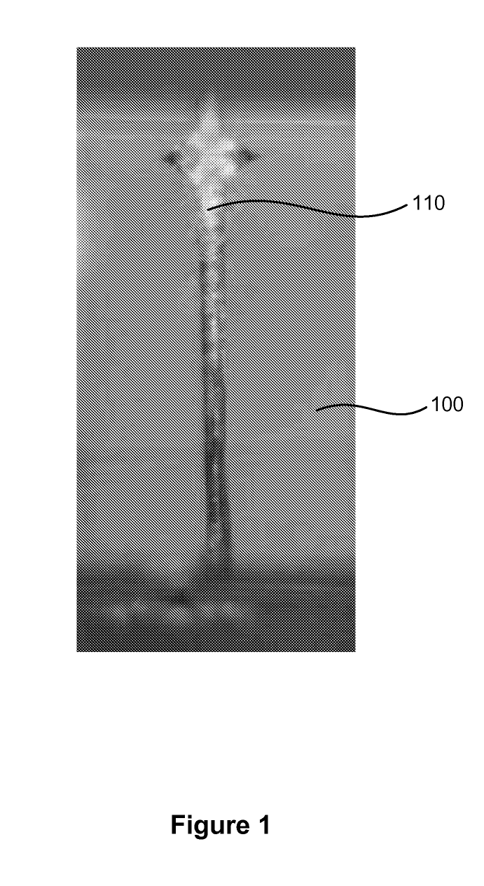

Vias can be formed in the glass substrates. FIG. 1 shows an image of a cross-section of a glass substrate with a through-glass via. High aspect (depth to width) ratio vias 110 can be formed in a glass substrate 100, which can include an aspect ratio of 5 to 1 or greater, such as 10 to 1 or greater. In some implementations, the via 110 can have a depth (height) between about 50 microns and about 500 microns. The depth of the via 110 can correspond with the thickness of the glass substrate 100. In some implementations, the via 110 can have a width (diameter) greater than about 8 microns, such as between about 8 microns and 50 microns.

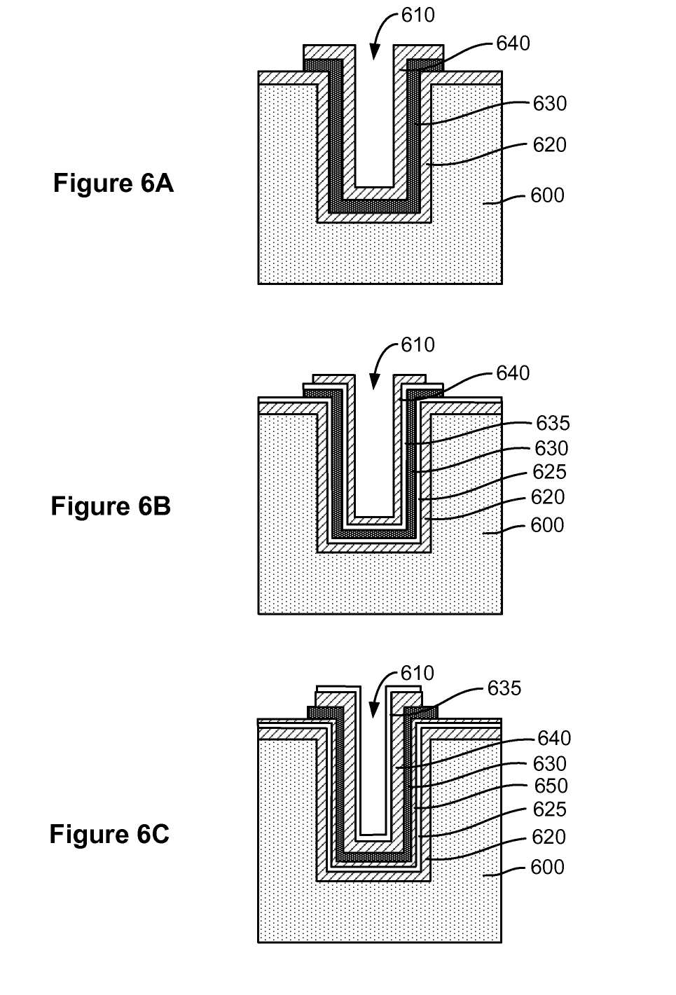

The vias 110 at least partially extend through the glass substrate 100. In some implementations, as illustrated in the image in FIG. 1, the via 110 can extend through the glass substrate 100 to form a through-glass via (TGV). A TGV can provide interconnection to components on both sides of the glass substrate 100. In some implementations, vias may extend partially through the glass substrate 100 to form blind vias, such as the blind vias illustrated in FIGS. 6A-6C. The blind vias also can have a high aspect ratio and have a bottom area used to improve capacitance.

In some implementations, the TGVs described herein formed in glass substrates have higher aspect ratios and/or widths greater than those in through-silicon vias (TSVs), semiconductor device damascene structures, and the like. For example, through-silicon vias (TSVs) typically have vias with aspect ratios of less than about 5 to 1 and damascene structures in semiconductor devices typically have vias with aspect ratios of 2 to 1 or less.

The via 110 may be formed by a variety of techniques, including but not limited to laser drilling, sandblasting, etching, or a combination of processes. Relative to sandblasting, laser drilling can typically and more readily achieve higher aspect ratio vias. The via 110 can be formed in photoglass using patterning techniques, such as photolithography, to transfer patterns from a mask to the photoglass.

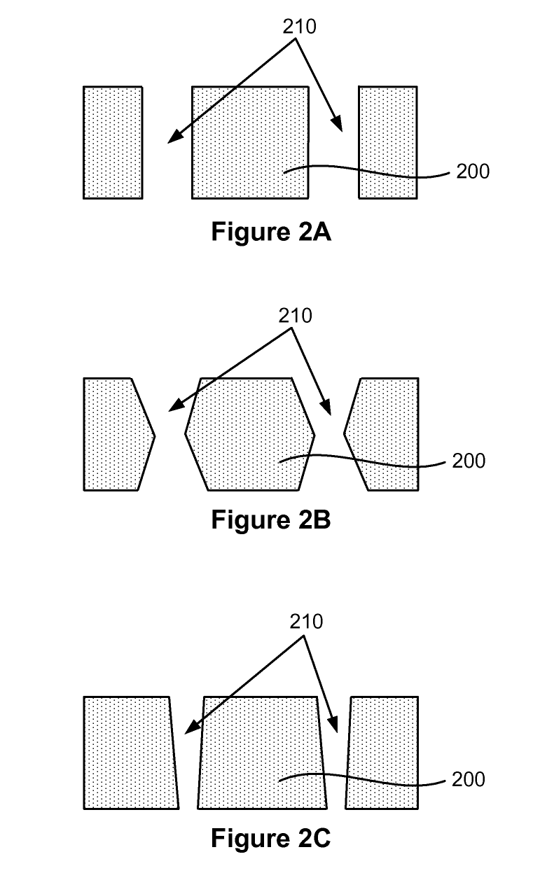

FIGS. 2A-2C are examples of cross-sectional schematic illustrations of through-glass vias. In some implementations, TGVs 210 can be formed in glass substrates 200 in various shapes or sizes. FIG. 2A illustrates a TGV 210 with a linear sidewall contour. FIG. 2B illustrates a TGV 210 with an hourglass sidewall contour. FIG. 2C illustrates a TGV 210 with a tapered sidewall contour. In some implementations, as illustrated in the example in FIG. 2C, a diameter of the top of TGV 210 can be greater than a diameter of the bottom of TGV 210. For example, the top can have a diameter between about 30 microns and about 50 microns, and the bottom can have a diameter between about 8 microns and about 10 microns. In addition, the shape of the opening of the TGV 210 can be any appropriate shape including circular, elliptical, hexagonal, octagonal, etc.

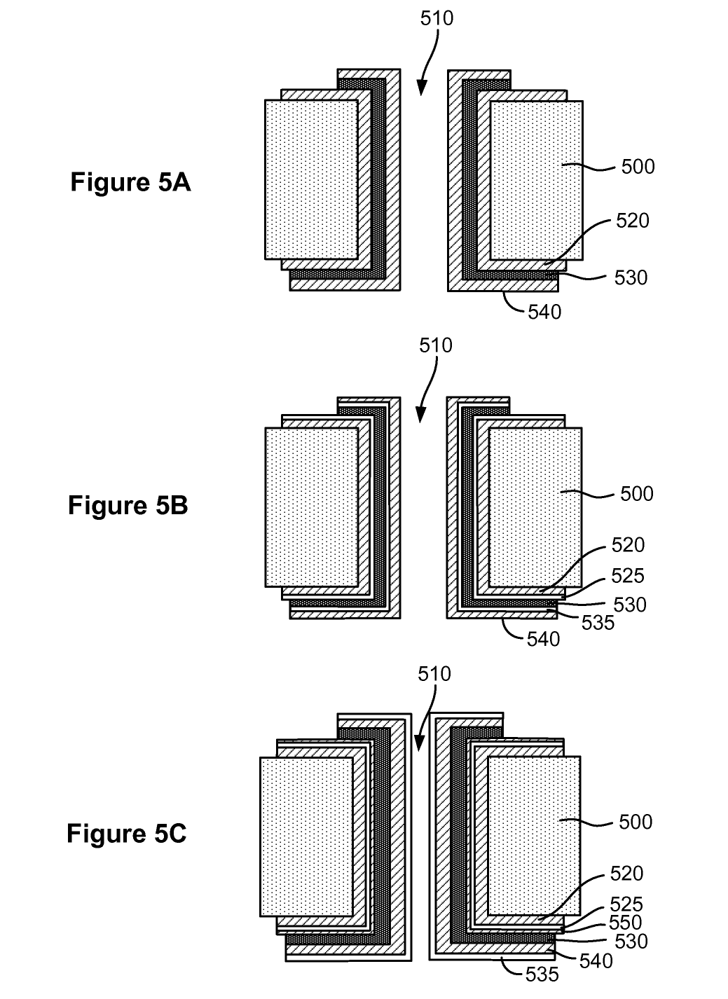

In some implementations, the TGVs described herein can include one or more materials formed on interior surfaces to form, for example, an electrical interconnect or other structure. For example, as described further below with respect to FIGS. 5A and 5B, a MIM capacitor can be formed in a TGV. Also provided are methods of forming materials on an interior surface of a TGV. The methods described herein overcome several challenges associated with forming materials on interior surfaces of TGVs. One challenge is that deposition of materials on glass generally occurs at low processing temperatures. Another challenge is forming substantially conformal and continuous thin films in TGVs, especially high aspect ratio TGVs. Such thin films can include seed layers for high aspect ratio TGVs and other substantially vertical wall microstructures. Sputter-deposited thin films of nitrides, metals, dielectric oxides, and other materials may not be able to adhere to and/or conformally and continuously deposit on the interior surfaces of a TGV. As a result, it can be difficult to form an electrical interconnect or electrical component such as a capacitor on the interior surfaces of a TGV. Forming copper (Cu) on glass can present particular challenges. For one, Cu exhibits poor adhesion when deposited directly on glass. In addition, nucleation of Cu is difficult on glass, the difference in CTE between Cu and glass is high, and Cu ions can migrate into glass at room temperature.

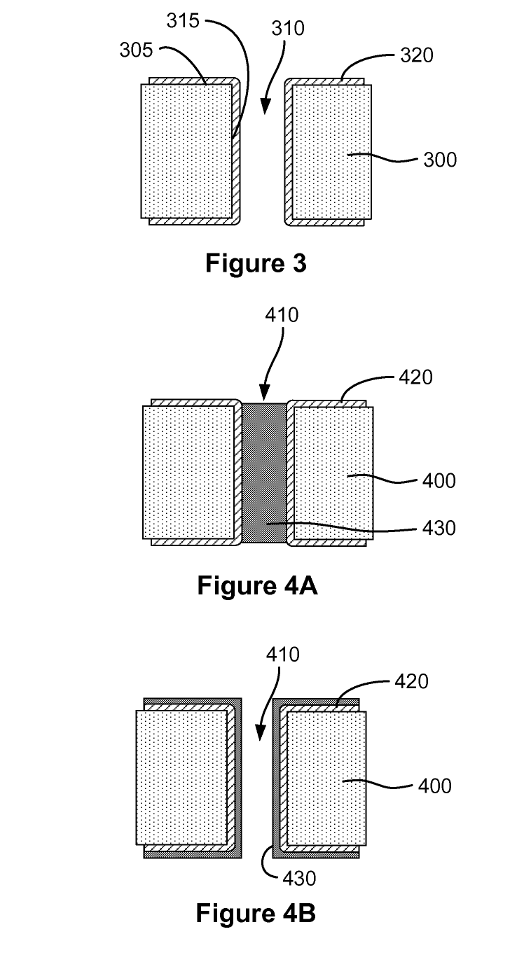

FIG. 3 is an example of a cross-sectional schematic illustration of an adhesive metal nitride layer disposed on the surface of a glass substrate and on the interior surfaces of a through-glass via. The adhesive metal nitride layer 320 can be disposed on the surface of the glass substrate 300 and on one or more interior surfaces of the via 310. The adhesive metal nitride layer 320 can be in direct contact with the surface of the glass substrate 300 and the interior surfaces of the via 310. In some implementations, the adhesive metal nitride layer 310 includes at least one of titanium nitride (TiN) and tantalum nitride (TaN).

The adhesive metal nitride layer 320 can be relatively thin. For example, the adhesive metal nitride layer 320 can be between about 3 nm and about 50 nm, such as between about 15 nm and about 25 nm. In some implementations, the adhesive metal nitride layer 320 can be deposited by atomic layer deposition (ALD). The ALD process can be thermal-enhanced or plasma-enhanced. An ALD-deposited layer of material can be very thin.

The ALD technique is well-suited for precise tailoring of very thin films with film growth as fine as about 0.1 nm per cycle. To grow films by the ALD technique, a substrate can be placed in a reaction chamber where process conditions, including temperature, pressure, precursor dosage, and purging times are adjusted to meet the requirements of the process chemistry and the substrate materials. In some implementations, the temperature is in the range of about 20° C. to about 600° C., and the pressure in the range of about 1 Pa to about 1000 Pa. Typically, ALD processing temperatures for a glass substrate can be below about 480° C. to avoid warpage.

A first precursor can be directed over the substrate, with at least some of the first precursor chemisorbing or physisorbing onto the surface of the substrate to form a monolayer. A purge gas can be introduced to remove non-reacted precursors and gaseous reaction by-products. A second precursor can be introduced which can react with the monolayer of the first precursor, with a purge gas subsequently introduced to remove excess precursors and gaseous reaction by-products. This completes one cycle. The precursors can be alternately pulsed into the reaction chamber with minimal or no overlap.

It will be understood that any of the ALD-deposited metal nitride layers can be made using different combinations of precursors. For example, in some implementations, to deposit by ALD a layer of TiN, a first precursor of tetrakis-dimethylamino titanium (TDMAT) or tetrakis-ethylmethylamino titanium (TEMAT) may react with a second precursor of ammonium (NH₃), nitrogen (N₂), or N₂ and hydrogen (H₂). In some implementations, to deposit by ALD a layer of TiN, a first precursor of titanium tetrachloride (TiCl₄) may react with a second precursor of NH₃, N₂, or N₂ and H₂. In some implementations, precursors may be alternatingly pulsed into a reaction chamber without intervening pulses of purge gases.

The desired thickness of the ALD-deposited metal nitride layers can be controlled by the number of reaction cycles. One cycle may take time from about 0.5 seconds to a few tens of seconds and deposit between about 0.1 nm and about 0.4 nm thickness of material. Thus, each of the ALD-deposited metal nitride layers in the range of about 3 nm and about 50 nm in thickness can be precisely tailored within about 0.1 nm accuracy.

As illustrated in the example in FIG. 3, the adhesive metal nitride layer 320 can be conformally deposited and continuous on the surface of the glass substrate 300 and on the interior surfaces 315 of the via 310 and on a portion of exterior surfaces 305 of the glass substrate 300 that surround the via 310. The adhesive metal nitride layer 320 can have a relatively high uniformity. In some implementations, the adhesive metal nitride layer 320 can be continuous with a thickness uniformity of greater than about 75% (or thickness non-uniformity of less than about 25%).

The ALD technique is also well-suited for achieving high conformality and uniformity over large areas. The clean and precise self-limiting nature of ALD can enable ALD-deposited thin films to be highly conformal and continuous. Thus, ALD can provide excellent step coverage in a variety of aggressively shaped structures, including high aspect ratio vias.

The adhesive metal nitride layer 320 can serve a variety of functions. In some implementations, the adhesive metal nitride layer 320 can serve as an adhesion layer for subsequently deposited materials. For example, a thin film of TiN or TaN can improve the adhesion of Cu over glass. In some implementations, the adhesive metal nitride layer 320 can serve as a diffusion barrier layer to reduce the migration of metal atoms/ions into adjacent dielectric or semiconductor regions. For example, a thin film of TiN or TaN can reduce the migration of Cu ions into glass, and help reduce insertion loss. In some implementations, the adhesive metal nitride layer 320 is a seed layer for subsequently deposited materials. For example, a thin film of TiN or TaN can serve as a seed layer in a high aspect ratio via for Cu. Nucleation of Cu on a glass surface, including the interior surfaces of the via 310, can be very difficult without the adhesive metal nitride layer 320. The use of an adhesive metal nitride layer 320 as a seed layer can facilitate building thin film stacks or various nanostructures or microstructures in a high aspect ratio via. Furthermore, because the adhesive metal nitride layer 320 has a CTE of about 9.4×10⁻⁶ /° C., which is between the CTE of Cu (˜17×10⁻⁶/° C.) and the CTE of glass (˜8.5×10⁻⁶ /° C.), the adhesive metal nitride layer 320 can provide a more similar CTE match between Cu and glass. The adhesive metal nitride layer 320 can serve a combination or all of these functions, as none of the functions described herein is mutually exclusive of any other.

FIG. 4A is an example of a cross-sectional schematic illustration of a copper fill over an adhesive metal nitride layer in a through-glass via. FIG. 4B is an example of a cross-sectional schematic illustration of a Cu thin film over an adhesive metal nitride layer in a through-glass via. An adhesive metal nitride layer 420 can be disposed on the surface of a glass substrate 400 and on the interior surfaces of a via 410, as discussed earlier herein. A Cu layer 430 can be formed over the adhesive metal nitride layer 420. As illustrated in the examples in FIGS. 4A-4B, the Cu layer 430 is formed directly on at least a portion of the adhesive metal nitride layer 420.

In some implementations, as illustrated in the example in FIG. 4A, the Cu layer 430 substantially fills the via 410. The Cu layer 430 can serve as an electrically conductive interconnect through the via 410 and be part of an interposer. An interposer generally serves as an intermediate layer that can be used for direct electrical interconnection between one device or substrate and a second device or substrate with the interposer positioned in between. Interposers can be incorporated in various device packages, such as packages for memory, logic, EMS, MEMS, and other chip devices. For example, the interposer can be implemented in one or more application specific integrated circuits (ASICs), digital signal processors (DSPs), digital signal processing devices (DSPDs), programmable logic devices (PLDs), field programmable gate arrays (FPGAs), memory stacks, processors, controllers, microcontrollers, and other electronic devices. In some implementations, the interposer can be used to communicate data to a processor (such as a processor 21 in FIG. 9).

The Cu layer 430 can serve as interconnect posts in the interposer. The interposer can include a routing or redistribution layer (RDL) with a plurality of Cu interconnect posts. High aspect ratio vias in the glass substrate 400 can provide, for example, high wiring density interconnection in the interposer.

In some implementations, as illustrated in the example in FIG. 4B, the Cu layer 430 forms a thin film over the adhesive metal nitride layer 420 and does not fill the via 410. The Cu layer 430 can form part of a thin film stack on a nanostructured or microstructured surface of the glass substrate 400. For example, the thin film stack can be part of an integrated passive device (IPD), such as a capacitor, inductor, or resistor. The IPDs may be used as part of a variety of devices, such as RF devices.

The Cu layer 430 can be deposited or otherwise formed using any suitable technique. In some implementations, the Cu layer 430 is formed by electroplating. The adhesive metal nitride layer 420 can be a seed layer for the electroplating of Cu.

In some implementations, the Cu layer 430 is formed by an electroless and/or electrolytic technique. For example, the electroplating of Cu can include plating a Cu seed layer by an electroless process, and then plating a thicker Cu layer by an electrolytic process. The Cu layer 430 can include a very thin layer of electroless Cu that can serve as a Cu seed layer, upon which a thicker layer of electrolytic Cu is formed. The thicker Cu layer is used to reduce the resistance of the electrode layer. The use of electroplated Cu enables a decrease in equivalent series resistance (ESR).

FIGS. 5A-5C are examples of cross-sectional schematic illustrations of an adhesive metal nitride layer as part of a capacitor in a through-glass via according to varying implementations. As illustrated in the example in FIG. 5A, an adhesive metal nitride layer 520 can be formed on the surface of a glass substrate 500 and on the interior surfaces of the via 510. The adhesive metal nitride layer 520 can serve as a seed layer for subsequently deposited thin films. A dielectric layer 530 is formed over the adhesive metal nitride layer 520. The dielectric layer 530 can form a thin film that substantially conforms to the adhesive metal nitride layer 520 within the via 510 and over a portion of the surface of the glass substrate 500. An outer metal nitride layer 540 is formed over the dielectric layer 530. As used herein, an outer layer can mean a layer disposed further away from the surface of the glass substrate 500 relative to one or more layers disposed on the surface of the glass substrate 500, or an outer layer can mean a layer disposed further away from the interior surfaces of the via 510 relative to one or more layers disposed on the interior surfaces of the via 510. The outer metal nitride layer 540 can form a thin film that substantially conforms to the dielectric layer 530 within the via 510 and over a portion of the surface of the glass substrate 500. The adhesive metal nitride layer 520, the dielectric layer 530, and the outer metal nitride layer 540 form part of a capacitor in the via 510, such as a MIM capacitor.

In some implementations, the dielectric layer 530 can be a dielectric oxide. For example, the dielectric oxide can include but is not limited to aluminum oxide (Al₂O₃) and zirconium oxide (ZrO₂). The dielectric layer 530 can have a thickness between about 5 nm and about 100 nm.

In some implementations, the outer metal nitride layer 540 can include at least one of TiN and TaN. In some implementations, the outer metal nitride layer 540 can be substantially identical in thickness and composition as the adhesive metal nitride layer 520. In some implementations, the outer metal nitride layer 540 can be thicker than the adhesive metal nitride layer 520.

Each of the adhesive metal nitride layer 520, the dielectric layer 530, and the outer metal nitride layer 540 can be formed by ALD. Deposition by ALD can achieve precise tailoring of very thin films and highly conformal thin films in a high aspect ratio via. Thus, vertical wall, or nearly vertical wall, nanostructures and microstructures, including high-density sidewall capacitors, can be built in high aspect ratio TGVs.

As illustrated in the example in FIG. 5B, Cu layers 525 and 535 can be formed between the dielectric layer 530 and each of the metal nitride layers 520 and 540. The Cu layers 525 and 535 can be formed using electroless and/or electrolytic techniques. With Cu layers 525 and 535 surrounding the exterior and interior surface of the dielectric layer 530, the ESR in the capacitor can be reduced, which improves the performance of the capacitor. The Cu layers 525 and 535 can serve as metal layers in a MIM capacitor.

Cu layers 525 and 535 deposited directly on the dielectric layer 530 can cause the Cu layers 525 and 535 to oxidize. In addition, electroless plating of Cu directly on the dielectric layer 530 can change the pH of the Cu and create pin holes in the dielectric layer 530. Thus, in some implementations, thin film layers of metal nitrides (not shown) can be deposited between the Cu layer 525 and dielectric layer 530, and between the Cu layer 535 and the dielectric layer 530.

In the example in FIG. 5C, the outer metal nitride layer 540 may be formed directly over the dielectric layer 530 and the Cu layer 535 may be formed directly over the outer metal nitride layer 540. The outer metal nitride layer 540 may also be referred to as an interface layer or interface metal nitride layer, or as a buffer layer. As such, the outer metal nitride layer 540 may serve as an adhesion layer for the Cu layer 535, and the outer metal nitride layer 540 may serve as a diffusion barrier to reduce the migration of Cu atoms into the dielectric layer 530. Further, the presence of the outer metal nitride layer 540 reduces the presence of pin holes in the dielectric layer 530 compared to a structure in which the Cu layer 535 is formed directly on dielectric layer 530. Cu layers 525 and 535 may be deposited using any suitable deposition described earlier herein. In some implementations, the Cu layer 535 may be thicker than the Cu layer 525.

In addition, a capping layer 550 may be formed between the Cu layer 525 and the dielectric layer 530. The capping layer 550 may also be referred to as a buffer layer or an interface layer. The capping layer 550 may include a metal nitride, such as TiN and TaN, but may also include palladium (Pd), tantalum (Ta), molybdenum (Mo), or alloys thereof. Other materials, including metals, metal alloys, and dielectrics, may also be used as a capping layer. In some implementations, the capping layer 550 may serve as a barrier to reduce the migration of Cu atoms into the dielectric layer 530. Capping layer 550 may be considered a first buffer layer and the outer metal nitride layer 540 may be considered a second buffer layer. In some implementations, a protective metal nitride layer (not shown) may be formed over the Cu layer 535.

FIGS. 6A-6C are examples of cross-sectional schematic illustrations of an adhesive metal nitride layer as part of a capacitor in a blind via according to varying implementations. Rather than extending through the glass substrate 600, a blind via 610 extends partially through the glass substrate 600. The blind via 610 also may have a high depth to width aspect ratio, such as about 5 to 1 or greater, or about 10 to 1 or greater. The blind via 610 also provides a bottom area used to improve capacitance.

In the example in FIG. 6A, an adhesive metal nitride layer 620 may be formed on the surface of the glass substrate 600 and on the interior surfaces of the blind via 610, including the bottom interior surface of the blind via 610. A dielectric layer 630 is formed over the adhesive metal nitride layer 620. An outer metal nitride layer 640 is formed over the dielectric layer 630. The dielectric layer 630 may serve as a dielectric between the adhesive metal nitride layer 620 and the outer metal nitride layer 640, which may serve as electrical conductors for a capacitor. Hence, the adhesive metal nitride layer 620, the dielectric layer 630, and the outer metal nitride layer 640 form part of a capacitor in the blind via 610, such as a MIM capacitor.

In the example in FIG. 6B, Cu layers 625 and 635 can be formed between the dielectric layer 630 and each of the metal nitride layers 620 and 640. The Cu layers 625 and 635 may serve as metal layers in a MIM capacitor.

In the example in FIG. 6C, the outer metal nitride layer 640 may be formed directly over the dielectric layer 630 and the Cu layer 635 may be formed directly over the outer metal nitride layer 640. The outer metal nitride layer 640 may also be referred to as an interface layer or interface metal nitride layer, or as a buffer layer. The outer metal nitride layer 640 may serve as an adhesion layer for Cu layer 635 and as a diffusion barrier to reduce the migration of Cu atoms into the dielectric layer 630.

Moreover, a capping layer 650 may be formed between the Cu layer 625 and the dielectric layer 630. The capping layer 650 may be referred to as a buffer layer or interface layer. The capping layer 650 may include any suitable metal, including but not limited to TiN, TaN, Pd, Ta, Mo, and alloys thereof. Other materials, including metals, metal alloys, and dielectrics, may also be used as a capping layer. In some implementations, the capping layer 650 may serve as a barrier to reduce the migration of Cu atoms into the dielectric layer 630. In some implementations, a protective metal nitride layer (not shown) may be formed over the Cu layer 635. Capping layer 650 may be considered a first buffer layer and the outer metal nitride layer 640 may be considered a second buffer layer.

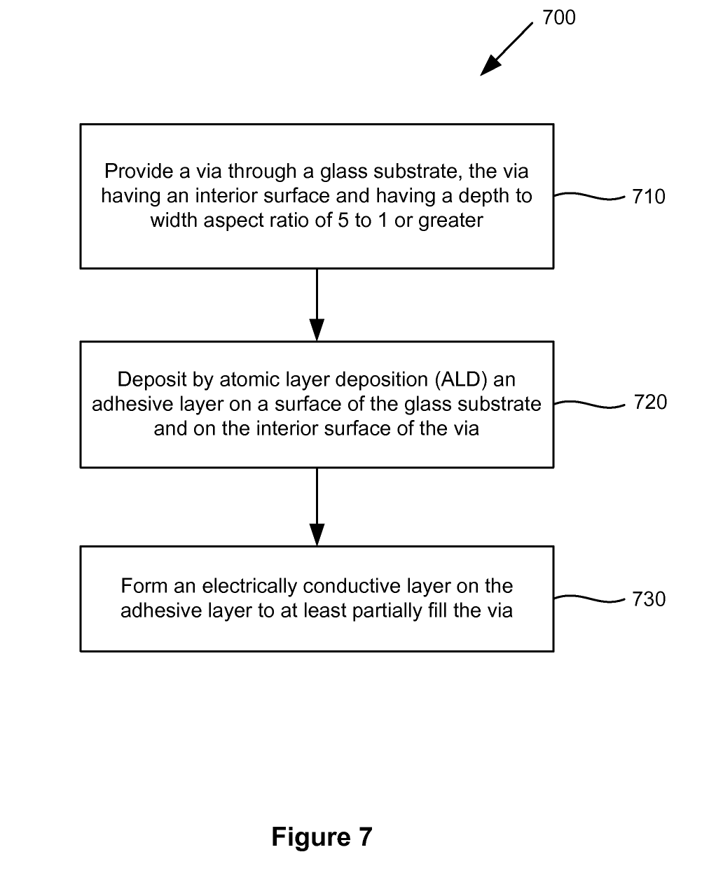

FIG. 7 is an example of a flow diagram illustrating a method of forming an electrically conductive layer on an adhesive layer to at least partially fill a via through a glass substrate. It is understood that additional processes not shown in FIG. 6 may also be present.

The process 700 begins at block 710 where a via is provided through a glass substrate. The via has an interior surface and has a depth to width aspect ratio of 5 to 1 or greater. In some implementations, the aspect ratio of depth to width is 10 to 1 or greater. The via can be formed using any suitable techniques such as laser drilling, sandblasting, etching, or combinations thereof. The glass substrate can have a thickness between about 50 microns and about 1100 microns. The via can have a diameter between about 8 microns and about 50 microns.

Forming a TGV can be a double-sided process or single-side process. A double-sided process of forming a TGV can involve forming two cavities or partially through holes, one on each side of the glass substrate. At some point during or after formation of these two partially through holes, they are joined by etching or otherwise removing glass material between them. The two partially through holes are aligned such that when joined, the aligned through holes overlap near a mid-section of the glass substrate, forming the TGV. Double-sided processes can involve one or more of simultaneous wet or dry etching of aligned partially through holes, sequential wet or dry etching of aligned partially through holes, simultaneous or sequential laser drilling of aligned partially through holes, and simultaneous or sequential sandblasting of aligned partially through holes according to the desired implementation. Forming a blind via hole is generally a single-sided process.

As indicated above, in some implementations, the glass substrate can be a photoglass. Photoglasses can include silicon oxide/lithium oxide (SiO₂/Li₂O)-based glasses doped with one or more noble metals such as silver (Ag) and cerium (Ce). Forming a via in photoglass can include treating the photoglass with ultraviolet (UV) radiation and heat to render the treated portions of the photoglass etchable with etchants such as hydrofluoric (HF) acid. For example, a photoglass masked with a quartz chromium mask may be exposed to UV radiation to pattern a via. Examples of photoglasses include APEX™ glass photo-definable glass wafers by Life BioScience, Inc. and Forturan™ photo-sensitive glass by Schott Glass Corporation.

In some implementations, forming a via can involve forming a mask on one or both sides of the glass substrate. Forming a mask generally involves applying a photo-sensitive layer on the glass substrate, exposing a pattern lithographically into the photo-sensitive layer, and then developing the photo-sensitive layer. Alternatively, an etch-resistant layer deposited on the glass substrate can be patterned and etched, and then serve as an etch mask. Stencils or other masking techniques may also be used as masks for wet, dry, or sandblasting operations. The masks are formed to correspond to the placement and size of the via. In some implementations, the masks on the top and bottom surfaces are mirror images, with mask openings on either side of the substrate aligned to allow formation of aligned partially through via holes and the subsequent through-glass via hole. To form a TGV having differently sized openings on the top and bottom side of the substrate, differently sized, yet aligned mask openings in the masks may be formed.

For isotropic removal processes such as isotropic wet chemical etches, the mask openings can be substantially smaller than the eventual desired via opening size. For example, for a circular via opening having a 50 micron diameter, the mask opening may be as small as about 1-20 microns, such as about 10 microns. For anisotropic removal processes such as sandblasting or dry etching, the mask opening is generally about the size of or smaller than the size of the eventual desired via opening size. The mask material may be selected depending on the subsequent glass removal operation. For wet etching, mask materials may include photoresist, deposited layers of polysilicon or silicon nitride, silicon carbide, or thin metal layers of chrome, chrome and gold, or other etch-resistant material. For sandblasting, mask materials include photoresist, a laminated dry-resist film, a compliant polymer, a silicone rubber, a metal mask, or a metal or polymeric screen. For some techniques such as laser drilling, forming a via may not involve applying a mask to the glass substrate surface. However, in some other implementations, a mask may be interposed between the laser and the glass substrate.

The glass substrate may be provided with or without EMS devices and/or other components already fabricated on one or both sides of the substrate. In some implementations, EMS and other devices may be formed during or after formation of the via. In some implementations, vias may be formed before or after the formation of an EMS device on one side of the glass substrate. Subsequently, an electronic device may be either formed on the opposing side of the glass substrate, or a packaged electronic device may be mounted or attached on the opposing side of the glass substrate. The electronic device may include a passive formed on the glass substrate or a packaged silicon chip, such as a processor, driver, or memory device. Once filled with a conductive material, the EMS device may be in electronic communication with the electronic device through a conductor formed inside the via.

The process 700 continues at block 720 where an adhesive layer is deposited by ALD on the surface of the glass substrate and on the interior surface of the via. In some implementations, the adhesive layer can include at least one of TiN and TaN. The adhesive layer can have a thickness between about 3 nm and about 50 nm. Examples of titanium-containing precursors that may be used to deposit TiN by ALD include TDMAT, TEMAT, and TiCl₄. Examples of tantalum-containing precursor that may be used to deposit TaN include tantalum pentachloride (TaCl₅), pentakis-dimethylamino tantalum (PDMAT), pentakis-ethylmethylamino tantalum (PEMAT), and tert-butylimino-tris-diethylamino tantalum (TBTDET).

The process 700 continues at block 730 where an electrically conductive layer is formed on the adhesive layer to at least partially fill the via. In some implementations, the electrically conductive layer includes at least one of electroless Cu and electrolytic Cu. Thus, a thin film stack of metal nitride/electroless Cu/plated Cu can be formed in the via.

In some implementations, a capping layer, such as a first buffer metal nitride layer, can be deposited over the electrically conductive layer, and a dielectric layer can be deposited over the capping layer, where the dielectric layer can have a thickness between about 5 nm and about 100 nm. The capping layer can include a metal nitride layer, such as TiN and TaN, but may also include Pd, Ta, Mo, or alloys thereof. Other materials, including metals, metal alloys, and dielectrics, may also be used as a capping layer. An interface layer can be deposited over the dielectric layer, and a Cu layer can be deposited over the interface layer. In implementations where the capping layer is a metal nitride layer, the interface layer deposited over the dielectric layer may be considered a second buffer metal nitride layer. In some implementations, a protective layer, such as a protective metal nitride layer, can be deposited over the Cu layer. The capping layer (for example, a first buffer metal nitride layer), the interface layer (for example, a second buffer metal nitride layer for implementations where the capping layer is a metal nitride layer), and the protective layer (for example, a protective metal nitride layer for implementations where the interface and the capping layers are metal nitride layers) can include at least one of TiN and TaN. In some implementations, the dielectric layer can include at least one of Al₂O₃ and ZrO₂. Each of the layers can be deposited by ALD. Examples of precursors to deposit Al₂O₃ by ALD include trimethylaluminum (TMA) and tris-diethylamino aluminum (TDEAA). Examples of precursors to deposit ZrO₂ by ALD include tetrakis-dimethylamino zirconium (TDMA) and tetrakis-ethylmethylamino zirconium (TEMA). The adhesive layer, the electrically conductive layer, the first buffer metal nitride layer, the dielectric layer, the second buffer metal nitride layer, the Cu layer, and the protective metal nitride layer can form an MIM capacitor in the via.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of, e.g., an IMOD display element as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising:
a glass substrate having a surface;
a via extending at least partially through the glass substrate from the surface, the via having a depth to width aspect ratio of 5 to 1 or greater; and
an adhesive metal nitride layer disposed on the surface of the glass substrate and on one or more interior surfaces of the via, wherein the adhesive metal nitride layer includes at least one of titanium nitride (TiN) and tantalum nitride (TaN).

2. The apparatus of claim 1, wherein the via extends entirely through the glass substrate.

3. The apparatus of claim 2, wherein the adhesive metal nitride layer is conformally deposited on the surface of the glass substrate and on the one or more interior surfaces of the via and continuously coats the one or more interior surfaces of the via.

4. The apparatus of claim 2, further comprising a copper (Cu) layer on the adhesive metal nitride layer.

5. The apparatus of claim 4, wherein the Cu layer substantially fills the via and forms part of an electrically conductive interconnect of an interposer.

6. The apparatus of claim 4, wherein the Cu layer includes at least one of electroless Cu and electroplated Cu.

7. The apparatus of claim 2, wherein the via has a depth between about 50 μm and about 500 μm.

8. The apparatus of claim 2, wherein the via has a width greater than about 8 μm.

9. The apparatus of claim 1, further comprising:
a dielectric layer over the adhesive metal nitride layer; and
an outer metal nitride layer over the dielectric layer, wherein the outer metal nitride layer includes at least one of TiN and TaN, and wherein the adhesive metal nitride layer, the dielectric layer, and the outer metal nitride layer form part of a metal-insulator-metal (MIM) capacitor in the via.

10. The apparatus of claim 9, wherein the dielectric layer includes at least one of aluminum oxide and zirconium oxide.

11. The apparatus of claim 9, further comprising:
a first Cu layer between dielectric layer and the adhesive metal nitride layer; and
a second Cu layer between the dielectric layer and the outer metal nitride layer.

12. The apparatus of claim 9, further comprising:
a first Cu layer between the dielectric layer and the adhesive metal nitride layer; and
a second Cu layer over the outer metal nitride layer.

13. The apparatus of claim 9, further comprising:
a Cu layer between the dielectric layer and the adhesive metal nitride layer; and
a capping layer between the Cu layer and the dielectric layer.

14. The apparatus of claim 9, wherein the dielectric layer has a thickness between about 5 nm and about 100 nm.

15. The apparatus of claim 1, wherein the glass substrate has a thickness between about 50 μm and about 1100 μm.

16. The apparatus of claim 1, wherein the adhesive metal nitride layer has a thickness between about 3 nm and about 50 nm.

17. The apparatus of claim 1, wherein the adhesive metal nitride layer is a diffusion barrier.

18. An apparatus comprising:
a glass substrate having a surface;
a via extending at least partially from the surface through the glass substrate, the via having an interior surface and an aspect ratio of depth to width of 5 to 1 or greater;
means for adhering an electrically conductive material to glass disposed on the surface of the glass substrate and on the interior surface of the via; and
means for conducting electricity formed on the adhering means to at least partially fill the via, wherein the conducting means includes the electrically conductive material.

19. The apparatus of claim 18, wherein the adhering means includes at least one of titanium nitride (TiN) and tantalum nitride (TaN).

20. The apparatus of claim 18, wherein the electrically conductive material includes Cu.

21. The apparatus of claim 18, wherein the adhering means is conformally deposited on the surface of the glass substrate and on the interior surface of the via and continuously coated on the interior surface of the via.

22. The apparatus of claim 18, further comprising:
first buffering means for providing a buffer for the conducting means, wherein the first buffering means includes at least one of TiN and TaN;
means for insulating electricity formed over the first buffering means;
second buffering means for providing a buffer for the insulating means, wherein the second buffering means includes at least one of TiN and TaN; and
second means of conducting electricity formed over the second buffering means, wherein the second conducting means includes Cu.

23. The apparatus of claim 18, wherein the glass substrate has a thickness between about 50 μm and about 1100 μm.

24. A method comprising:
providing a via through a glass substrate, the via having an interior surface and having an aspect ratio of depth to width of 5 to 1 or greater;
depositing by atomic layer deposition (ALD) an adhesive layer on a surface of the glass substrate and on the interior surface of the via; and
forming an electrically conductive layer on the adhesive layer to at least partially fill the via.

25. The method of claim 24, wherein providing the via includes forming the via by laser drilling.

26. The method of claim 24, wherein the adhesive layer includes at least one of titanium nitride (TiN) and tantalum nitride (TaN).

27. The method of claim 24, wherein the adhesive layer has a thickness between about 3 nm and about 50 nm.

28. The method of claim 24, wherein the conductive layer includes at least one of electroless Cu and electroplated Cu.

29. The method of claim 24, further comprising:
depositing a first buffer metal nitride layer over the conductive layer; and
depositing a dielectric layer over the first buffer metal nitride layer, wherein the dielectric layer has a thickness between about 5 nm and about 100 nm.

30. The method of claim 29, further comprising:
depositing a second buffer metal nitride layer over the dielectric layer;
depositing a Cu layer over the second buffer metal nitride layer; and
depositing a protective metal nitride layer over the Cu layer, wherein the first buffer metal nitride layer, the second buffer metal nitride layer, and the protective metal nitride layer each include at least one of TiN and TaN.

31. An apparatus produced by the method as recited by claim 24.
